(19) United States
(12) Patent Application Publication
(10) Pub. No.: US 2017/0347493 A1
(43) Pub. Date: Nov. 30, 2017

(54) Structure Having Metal Material For Heat Radiation, Printed Circuit Board, Electronic Apparatus, And Metal Material For Heat Radiation

(71) Applicant: JX Nippon Mining & Metals Corporation, Tokyo (JP)

(72) Inventors: Hideta Arai, Ibaraki (JP); Atsushi Miki, Ibaraki (JP); Satoru Morioka, Tokyo (JP)

(21) Appl. No.: 15/607,739

(22) Filed: May 30, 2017

(30) Foreign Application Priority Data
May 31, 2016 (JP) 2016-109455
Jul. 12, 2016 (JP) 2016-138063

(51) Int. Cl. H05K 7/20; H05K 1/02

(52) U.S. Cl. CPC H05K 7/20481; H05K 1/021

(57) ABSTRACT

A structure having a metal material for heat radiation that is capable of favorably radiating heat from a heat generating component is provided. A structure having a metal material for heat radiation, comprising a heat generating component, a heat generating component protective member that is provided to cover a part or the entire of the heat generating component and to be spaced from the heat generating component, and a heat radiating member that is provided on a face of the heat generating component protective member on the side of the heat generating component to be spaced from a surface of the heat generating component on the side of the heat generating component protective member, wherein the heat radiating member contains a metal material for heat radiation at least on a surface of the heat radiating member on the side of the heat generating component.

### TECHNICAL FIELD

The present invention relates to a structure having a metal material for heat radiation, a printed circuit board, an electronic apparatus, and a metal material for heat radiation.

### BACKGROUND ART

Associated with the miniaturization and high definition of electronic apparatuses in recent years, there are problems including malfunctions and the like due to the heat generation of the electronic component used therein.

In view of the problems, for example, PTL 1 describes the research and development of the technique, in which a graphite sheet, which is a heat radiating member having a high thermal conductivity in the in-plane direction, is closely attached to the heat generating component directly or through an adhesive layer.

Electronic components and the like may be provided with a protective member for a purpose of shielding electromagnetic waves, and the like.

### CITATION LIST

### Patent Literature

[PTL 1] JP-A-2013-021357

### SUMMARY OF INVENTION

### Technical Problem

In the case where a cover is provided on a heat generating component, the heat tends to be accumulated in the cover, and the temperature of the heat generating component is hardly decreased. PTL 1 provides a measure of heat radiation on the side opposite to the side of the sealant (i.e., the side of the protective member) of the heat generating component. However, no measure is provided on the side of the sealant (i.e., the side of the protective member), and there is room for improvement.

Under the circumstances, an object to be achieved by the invention is to provide a structure having a metal material for heat radiation that is capable of favorably radiating heat from a heat generating component.

### Solution to Problem

As a result of earnest investigations made by the present inventors, it has been found that the object can be achieved by a structure having a metal material for heat radiation having a structure containing a heat generating component, a protective member that is provided to cover a part or the entire of the heat generating component and to be spaced from the heat generating component, and a heat radiating member that is provided on a face of the protective member on the side of the heat generating component to be spaced from a surface of the heat generating component on the side of the protective member, wherein the heat radiating member contains a metal material for heat radiation provided at least on a surface of the heat radiating member on the side of the heat generating component.

The invention having been completed based on the aforementioned knowledge provides, in one aspect, a structure having a metal material for heat radiation, comprising a heat generating component, a heat generating component protective member that is provided to cover a part or the entire of the heat generating component and to be spaced from the heat generating component, and a heat radiating member that is provided on a face of the heat generating component protective member on the side of the heat generating component to be spaced from a surface of the heat generating component on the side of the heat generating component protective member, wherein the heat radiating member contains a metal material for heat radiation at least on a surface of the heat radiating member on the side of the heat generating component.

In the structure having a metal material for heat radiation according to one embodiment of the invention, the heat radiating member is constituted by the metal material for heat radiation.

In the structure having a metal material for heat radiation according to another embodiment of the invention, the heat radiating member contains the metal material for heat radiation and a graphite sheet in this order from the side of the heat generating component.

In the structure having a metal material for heat radiation according to still another embodiment of the invention, the heat radiating member contains a plurality of the metal materials for heat radiation.

In the structure having a metal material for heat radiation according to still another embodiment of the invention, the heat radiating member contains a plurality of the graphite sheets.

In the structure having a metal material for heat radiation according to still another embodiment of the invention, the metal material for heat radiation has a thickness of 18 μm or more.

In the structure having a metal material for heat radiation according to still another embodiment of the invention, the metal material for heat radiation has a color difference ΔL based on JIS 28730 satisfying ΔL≦−40 on a surface of the metal material for heat radiation on the side of the heat generating component.

In the structure having a metal material for heat radiation according to still another embodiment of the invention, the metal material for heat radiation has a radiation factor of 0.03 or more on a surface of the metal material for heat radiation on the side of the heat generating component.

In the structure having a metal material for heat radiation according to still another embodiment of the invention, the metal material for heat radiation has a surface treatment layer provided on a surface of the metal material for heat radiation on the side of the heat generating component, and the surface treatment layer contains one or more layers selected from the group consisting of a roughening treatment layer, a heat resistant layer, a rust preventing layer, a chromate treatment layer, a silane coupling treatment layer, a plated layer, and a resin layer.

In the structure having a metal material for heat radiation according to still another embodiment of the invention, the metal material for heat radiation contains copper, a copper alloy, aluminum, an aluminum alloy, iron, an iron alloy, nickel, a nickel alloy, gold, a gold alloy, silver, a silver alloy, a platinum group metal, a platinum group metal alloy, chromium, a chromium alloy, magnesium, a magnesium alloy, tungsten, a tungsten alloy, molybdenum, a molybdenum alloy, lead, a lead alloy, tantalum, a tantalum alloy, tin, a tin alloy, indium, an indium alloy, zinc, or a zinc alloy.

In the structure having a metal material for heat radiation according to still another embodiment of the invention, the metal material for heat radiation contains copper, a copper alloy, aluminum, an aluminum alloy, iron, an iron alloy, nickel, a nickel alloy, zinc, or a zinc alloy.

In the structure having a metal material for heat radiation according to still another embodiment of the invention, the metal material for heat radiation contains phosphor bronze, Corson alloy, red brass, brass, nickel silver, or other copper alloys.

In the structure having a metal material for heat radiation according to still another embodiment of the invention, the metal material for heat radiation is a metal strip, a metal plate, or a metal foil.

In the structure having a metal material for heat radiation according to still another embodiment of the invention, the metal material for heat radiation has a surface roughness Sz of 5 μm or more measured with a laser microscope with laser light having a wavelength of 405 nm on a surface of the metal material for heat radiation on the side of the heat generating component.

In the structure having a metal material for heat radiation according to still another embodiment of the invention, the metal material for heat radiation has a surface roughness Sa of 0.13 μm or more measured with a laser microscope with laser light having a wavelength of 405 nm on a surface of the metal material for heat radiation on the side of the heat generating component.

In the structure having a metal material for heat radiation according to still another embodiment of the invention, the metal material for heat radiation has a surface roughness Sku of 6 or more measured with a laser microscope with laser light having a wavelength of 405 nm on a surface of the metal material for heat radiation on the side of the heat generating component.

In the structure having a metal material for heat radiation according to still another embodiment of the invention, the metal material for heat radiation satisfies one or more of the following items (1) to (5) on a surface of the metal material for heat radiation on the side of the heat generating component:

(1) the surface on the side of the heat generating component having a color difference ΔL based on JIS 28730 satisfying ΔL≦−40;

(2) the surface on the side of the heat generating component having a radiation factor of 0.03 or more;

(3) the surface on the side of the heat generating component having a surface roughness Sz of 5 μm or more measured with a laser microscope with laser light having a wavelength of 405 nm;

(4) the surface on the side of the heat generating component having a surface roughness Sa of 0.13 μm or more measured with a laser microscope with laser light having a wavelength of 405 nm; and

(5) the surface on the side of the heat generating component having a surface roughness Sku of 6 or more measured with a laser microscope with laser light having a wavelength of 405 nm.

In the structure having a metal material for heat radiation according to still another embodiment of the invention, the heat radiating member further contains a substance having thermal conductivity on a face of the heat radiating member on the side of the heat generating component.

In the structure having a metal material for heat radiation according to still another embodiment of the invention, the substance has a thermal conductivity of 0.5 W/(m·K) or more.

The invention provides, in another aspect, a printed circuit board containing the structure having a metal material for heat radiation according to the invention.

The invention provides, in still another aspect, an electronic apparatus containing the structure having a metal material for heat radiation according to the invention.

The invention provides, in still another aspect, a metal material for heat radiation containing one or more surfaces, at least one of the surfaces satisfying one or more of the following items (1) to (5), the metal material for heat radiation being to be adhered with a graphite sheet and to be used as a heat radiating member:

(1) the surface having a color difference ΔL based on JIS 28730 satisfying ΔL≦−40;

(2) the surface having a radiation factor of 0.03 or more;

(3) the surface having a surface roughness Sz of 5 μm or more measured with a laser microscope with laser light having a wavelength of 405 nm;

(4) the surface having a surface roughness Sa of 0.13 μm or more measured with a laser microscope with laser light having a wavelength of 405 nm; and

(5) the surface having a surface roughness Sku of 6 or more measured with a laser microscope with laser light having a wavelength of 405 nm.

### Advantageous Effects of Invention

According to the invention, a structure having a metal material for heat radiation that is capable of favorably radiating heat from a heat generating component can be provided.

### BRIEF DESCRIPTION OF DRAWINGS

FIG. 1 is a schematic cross sectional view showing a structure having a metal material for heat radiation according to one embodiment of the invention.

FIG. 2 is a schematic cross sectional view showing a structure having a metal material for heat radiation according to another embodiment of the invention.

FIG. 3 is schematic cross sectional views showing the structures of Examples 1 to 7, Comparative Example 1, and Reference Example 1.

FIG. 4 is schematic cross sectional views showing the structures of Examples 8 to 10 and 10′.

FIG. 5 is schematic cross sectional views showing the structures of Examples 11 to 16 and Reference Examples 2 to 4.

FIG. 6 is schematic cross sectional views showing the structures of Examples 17 to 21.

### DESCRIPTION OF EMBODIMENTS

The structure having a metal material for heat radiation of the invention contains a heat generating component, a heat generating component protective member that is provided to cover a part or the entire of the heat generating component and to be spaced from the heat generating component, and a heat radiating member that is provided on a surface of the heat generating component protective member on the side of the heat generating component to be spaced from a surface of the heat generating component on the side of the heat generating component protective member, and the heat radiating member contains a metal material for heat radiation at least on a surface of the heat radiating member on the side of the heat generating component. In the invention, the “heat generating component” means a member that generates heat, and may include, for example, an electric component, an application processor, an IC chip, and the like. The structure having a metal material for heat radiation of the invention may have a space between the heat generating component and the heat radiating member.

The heat generating component protective member is provided to cover a part or the entire of the heat generating component, and may include, for example, a heat generating component cover, an electromagnetic wave shielding material, an electromagnetic wave shielding cover, and the like. The heat generating component protective member may be any member that can absorb heat and radiate the heat outward, and examples of the material used therefor include various known materials including iron, copper, aluminum, magnesium, nickel, vanadium, zinc, magnesium, titanium, alloys of these metals, stainless steel, an inorganic material, ceramics (such as silicon nitride), a metal oxide, a compound, an organic material, graphene, graphite, carbon nanotubes, black lead, a conductive polymer, a high thermal conductive resin, a polycarbonate resin, a polyamide resin, a polybutylene terephthalate resin, a polyacetal resin, and a modified polyphenylene ether resin. The heat generating component protective member preferably has thermal conductivity.

The structure having a metal material for heat radiation of the invention has a heat radiating member that is provided on an inner face (i.e., a surface on the side of the heat generating component) of the heat generating component protective member, which is provided for the protection of the heat generating component, and the like, to be spaced from a surface of the heat generating component on the side of the heat generating component protective member. In the structure having the metal material for heat radiation having such a constitution, the heat radiating member contains a metal material for heat radiation at least on a surface of the heat radiating member on the side of the heat generating component. The metal material for heat radiation favorably conducts the heat from the heat generating component not only in the horizontal direction of the heat radiating member but also in the vertical direction (i.e., the thickness direction) thereof, and thus the heat from the heat generating component can be radiated by favorably conducting the heat to the heat generating component protective member. Accordingly, the heat of the heat generating component can be prevented from being accumulated in the inner space, so as to suppress malfunction of the heat generating component due to the temperature rise from occurring.

In particular, mobile equipments, such as a smartphone and a tablet PC, are being actively developed in recent years, and a smartphone, a tablet PC, and the like are undergoing the increase of the number of CPU mounted on the application processor and the increase of the operation clock frequency thereof, for running high load applications. The increase of the power consumption of the CPU thereby increases the temperature of the application processor, and actualizes the so-called “heat spot” problem, which causes low temperature burn injury on carrying the smartphone. The countermeasures for the heat spot include the decrease of the operation clock frequency and the force quit of the application in use on reaching a prescribed temperature, but these countermeasures have a problem that the highly functional application processor mounted cannot sufficiently exert the function thereof. The use of the structure having a metal material for heat radiation of the invention can radiate the heat from the application processor (heat generating component), and thus the temperature of the application processor (heat generating component) can be favorably suppressed from being increased, thereby the function of the highly functional application processor can be sufficiently exerted.

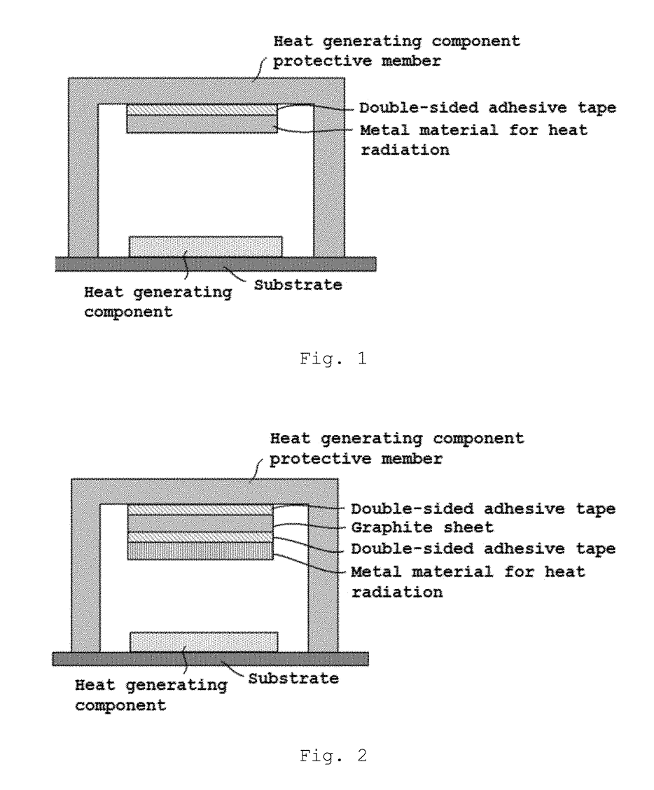

As shown in FIG. 1, for example, the structure having a metal material for heat radiation of the invention may contain a heat generating component, a heat generating component protective member that is provided to cover a part or the entire of the heat generating component and to be spaced from the heat generating component, and a heat radiating member that is provided on a face of the heat generating component protective member on the side of the heat generating component and to be spaced from a surface of the heat generating component on the side of the heat generating component protective member, and the heat radiating member may be constituted by a metal material for heat radiation. In the heat radiating member shown in FIG. 1, the metal material for heat radiation and the heat generating component protective member are fixed to each other with an adhesive tape (such as a double-sided adhesive tape) provided between them, but the constitution thereof is not limited thereto, and the adhesive tape may not be provided in the case where the metal material for heat radiation and the heat generating component protective member can be fixed to each other through pressure bonding or the like. In FIG. 1, while the heat generating component is provided on a substrate, a member having any form, on which the heat generating component can be provided, may be used, but not limiting to the substrate. The substrate may not be used.

As shown in FIG. 2, for example, the structure having a metal material for heat radiation of the invention may contain a heat generating component, a heat generating component protective member that is provided to cover a part or the entire of the heat generating component and to be spaced from the heat generating component, and a heat radiating member that is provided on a face of the heat generating component protective member on the side of the heat generating component to be spaced from a surface of the heat generating component on the side of the heat generating component protective member, and the heat radiating member may have a structure containing a metal material for heat radiation and a graphite sheet in this order from the side of the heat generating component. In the heat radiating member shown in FIG. 2, the metal material for heat radiation, the graphite sheet, and the heat generating component protective member are fixed to each other with adhesive tapes (such as double-sided adhesive tapes) provided among them, but the constitution thereof is not limited thereto, and the adhesive tapes may not be provided in the case where the metal material for heat radiation, the graphite sheet, and the heat generating component protective member can be fixed to each other through pressure bonding or the like. In FIG. 2, while the heat generating component is provided on a substrate, a member having any form, on which the heat generating component can be provided, may be used, but not limiting to the substrate. The substrate may not be used.

The heat radiating member of the structure having a metal material for heat radiation of the invention may contain a plurality of metal materials for heat radiation. The heat radiating member of the structure having a metal material for heat radiation of the invention may contain a plurality of graphite sheets.

The metal material for heat radiation used in the invention may be formed of copper, a copper alloy, aluminum, an aluminum alloy, iron, an iron alloy, nickel, a nickel alloy, gold, a gold alloy, silver, a silver alloy, a platinum group metal, a platinum group metal alloy, chromium, a chromium alloy, magnesium, a magnesium alloy, tungsten, a tungsten alloy, molybdenum, a molybdenum alloy, lead, a lead alloy, tantalum, a tantalum alloy, tin, a tin alloy, indium, an indium alloy, zinc, or a zinc alloy.

The metal material for heat radiation may be a metal strip, a metal plate, or a metal foil.

Typical examples of the copper include copper having a purity of 95% by mass or more, more preferably 99.90% by mass or more, such as a phosphorus-deoxidized copper (JIS H3100, alloy number: C1201, C1220, or C1221), an oxygen-free copper (JIS H3100, alloy number: C1020), and a tough pitch copper (JIS H3100, alloy number: C1100), and an electrolytic copper foil as defined in JIS H0500 and JIS H3100. Copper or a copper alloy containing one or more of Sn, Ag, Au, Co, Cr, Fe, In, Ni, P, Si, Te, Ti, Zn, B, Mn, and Zr in a total amount of from 0.001 to 4.0% by mass may also be used.

Examples of the copper alloy include phosphor bronze, Corson alloy, red brass, brass, nickel silver, and other copper alloys. The copper and copper alloys defined in JIS H3100 to JIS H3510, JIS H5120, JIS H5121, JIS C2520 to JIS C2801, and JIS E2101 to JIS E2102 can also be used in the invention. Herein, the JIS standards cited for showing the standards of metals are the JIS standards of the 2001 edition unless otherwise indicated.

The phosphor bronze typically means a copper alloy containing copper as the major component, Sn, and P in a smaller amount than Sn. As one example, the phosphor copper may have a composition containing from 3.5 to 11% by mass of Sn, from 0.03 to 0.35% by mass of P, and the balance of copper and unavoidable impurities. The phosphor bronze may contain elements including Ni, Zn, and the like in a total amount of 1.0% by mass or less.

The Corson alloy typically means a copper alloy containing an element that forms a compound with Si (for example, one or more of Ni, Co, and Cr) added thereto, which is precipitated as secondary phase particles in the mother phase. As one example, the Corson alloy may have a composition constituted by from 0.5 to 4.0% by mass of Ni, from 0.1 to 1.3% by mass of Si, and the balance of copper and unavoidable impurities. As another example, the Corson alloy may have a composition constituted by from 0.5 to 4.0% by mass of Ni, from 0.1 to 1.3% by mass of Si, from 0.03 to 0.5% by mass of Cr, and the balance of copper and unavoidable impurities. As still another example, the Corson alloy may have a composition constituted by from 0.5 to 4.0% by mass of Ni, from 0.1 to 1.3% by mass of Si, from 0.5 to 2.5% by mass of Co, and the balance of copper and unavoidable impurities. As still another example, the Corson alloy may have a composition constituted by from 0.5 to 4.0% by mass of Ni, from 0.1 to 1.3% by mass of Si, from 0.5 to 2.5% by mass of Co, from 0.03 to 0.5% by mass of Cr, and the balance of copper and unavoidable impurities. As still another example, the Corson alloy may have a composition constituted by from 0.2 to 1.3% by mass of Si, from 0.5 to 2.5% by mass of Co, and the balance of copper and unavoidable impurities. The Corson alloy may arbitrarily contain other elements (such as Mg, Sn, B, Ti, Mn, Ag, P, Zn, As, Sb, Be, Zr, Al, and Fe) added thereto. These elements may be added generally in a total amount up to approximately 5.0% by mass. For example, as still another example, the Corson alloy may have a composition constituted by from 0.5 to 4.0% by mass of Ni, from 0.1 to 1.3% by mass of Si, from 0.01 to 2.0% by mass of Sn, from 0.01 to 2.0% by mass of Zn, and the balance of copper and unavoidable impurities.

In the invention, the red brass means a copper alloy that is an alloy of copper and zinc containing zinc in an amount of from 1 to 20% by mass, and preferably from 1 to 10% by mass. The red brass may contain tin in an amount of from 0.1 to 1.0% by mass.

In the invention, the brass means a copper alloy that is an alloy of copper and zinc particularly containing zinc in an amount of 20% by mass or more. The upper limit of zinc is not particularly limited, and may be 60% by mass or less, and preferably 45% by mass or less or 40% by mass or less.

In the invention, the nickel silver means a copper alloy containing copper as the major component, containing from 60% by mass to 75% by mass of copper, from 8.5% by mass to 19.5% by mass of nickel, and from 10% by mass to 30% by mass of zinc.

In the invention, the other copper alloys mean copper alloys containing one kind or two or more kinds of Zn, Sn, Ni, Mg, Fe, Si, P, Co, Mn, Zr, Ag, B, Cr, and Ti in a total amount of 8.0% by mass or less, and the balance of copper and unavoidable impurities.

The aluminum and the aluminum alloy used may be, for example, one containing Al in an amount of 40% by mass or more, 80% by mass or more, or 99% by mass or more. Examples thereof used include aluminum and aluminum alloys defined in JIS H4000 to JIS H4180, JIS H5202, JIS H5303, and JIS 23232 to JIS 23263. For example, aluminum or an alloy having an Al content of 99.00% by mass or more represented by the aluminum alloy numbers 1085, 1080, 1070, 1050, 1100, 1200, 1N00, and 1N30 defined in JIS H4000 may be used.

The nickel and the nickel alloy used may be, for example, ones containing Ni in an amount of 40% by mass or more, 80% by mass or more, or 99.0% by mass or more. Examples thereof used include nickel and nickel alloys defined in JIS H4541 to JIS H4554, JIS H5701, JIS G7604 to JIS G7605, and JIS C2531. For example, nickel or an alloy having a Ni content of 99.0% by mass or more represented by the alloy numbers NW 2200 and NW2201 defined in JIS H4551 may be used.

The iron alloy used may be, for example, soft steel, carbon steel, an iron-nickel alloy, steel, or the like. Examples thereof used include iron and iron alloys defined in JIS G3101 to JIS G7603, JIS C2502 to JIS C8380, JIS A5504 to JIS A6514, and JIS E1101 to JIS E5402-1. The soft steel used may be soft steel having a carbon content of 0.15% by mass or less, and soft steel defined in JIS G3141 and the like may be used. The iron-nickel alloy used may contain Ni in an amount of from 35 to 85% by mass with the balance of Fe and unavoidable impurities, and specifically may be an iron-nickel alloy defined in JIS C2531.

The zinc and the zinc alloy used may be, for example, ones containing Zn in an amount of 40% by mass or more, 80% by mass or more, or 99.0% by mass or more. Examples thereof used include zinc and zinc alloys defined in JIS H2107 to JIS H5301.

The lead and the lead alloy used may be, for example, ones containing Pb in an amount of 40% by mass or more, 80% by mass or more, or 99.0% by mass or more. Examples thereof used include lead and lead alloys defined in JIS H4301 to JIS H4312 and JIS H5601.

The magnesium and the magnesium alloy used may be, for example, ones containing Mg in an amount of 40% by mass or more, 80% by mass or more, or 99.0% by mass or more. Examples thereof used include magnesium and magnesium alloys defined in JIS H4201 to JIS H4204, JIS H5203 to JIS H5303, and JIS H6125.

The tungsten and the tungsten alloy used may be, for example, ones containing W in an amount of 40% by mass or more, 80% by mass or more, or 99.0% by mass or more. Examples thereof used include tungsten and tungsten alloys defined in JIS H4463.

The molybdenum and the molybdenum alloy used may be, for example, ones containing Mo in an amount of 40% by mass or more, 80% by mass or more, or 99.0% by mass or more.

The tantalum and the tantalum alloy used may be, for example, ones containing Ta in an amount of 40% by mass or more, 80% by mass or more, or 99.0% by mass or more. Examples thereof used include tantalum and tantalum alloys defined in JIS H4701.

The tin and the tin alloys used may be, for example, ones containing Sn in an amount of 40% by mass or more, 80% by mass or more, or 99.0% by mass or more. Examples thereof used include tin and tin alloys defined in JIS H5401.

The indium and the indium alloy used may be, for example, ones containing In in an amount of 40% by mass or more, 80% by mass or more, or 99.0% by mass or more.

The chromium and the chromium alloy used may be, for example, ones containing Cr in an amount of 40% by mass or more, 80% by mass or more, or 99.0% by mass or more.

The silver and the silver alloy used may be, for example, ones containing Ag in an amount of 40% by mass or more, 80% by mass or more, or 99.0% by mass or more.

The gold and the gold alloy used may be, for example, ones containing Au in an amount of 40% by mass or more, 80% by mass or more, or 99.0% by mass or more.

The platinum group is the generic name for ruthenium, rhodium, palladium, osmium, iridium, and platinum. The platinum group metal and the platinum group metal alloy used may be, for example, ones containing at least one element selected from the element group of Pt, Os, Ru, Pd, Ir, and Rh in an amount of 40% by mass or more, 80% by mass or more, or 99.0% by mass or more.

The metal material for heat radiation preferably has a thickness of 18 μm or more. When the thickness of the metal material for heat radiation is less than 18 μm, there may be a possibility that the sufficient heat radiation effect cannot be obtained. The thickness of the metal material for heat radiation is more preferably 35 μm or more, further preferably 50 μm or more, still further preferably 65 μm or more, and still further preferably 70 μm or more.

The surface of the metal material for heat radiation on the side of the heat generating component preferably has a surface roughness Sz (i.e., the maximum height of the surface) of 5 μm or more measured with a laser microscope with laser light having a wavelength of 405 nm. When the surface roughness Sz of the surface of the metal material for heat radiation on the side of the heat generating component is less than 5 μm, there may be a possibility that the heat radiation property of the heat from the heat generating component becomes inferior. The surface roughness Sz of the surface of the metal material for heat radiation on the side of the heat generating component is preferably 7 μm or more, more preferably 10 μm or more, further preferably 14 μm or more, still further preferably 15 μm or more, and still further preferably 25 μm or more. The upper limit thereof is not particularly determined, and may be, for example, 90 μm or less, 80 μm or less, or 70 μm or less. In the case where the surface roughness Sz exceeds 90 μm, there may be a case where the productivity is reduced.

In the case where the metal material for heat radiation has a surface treatment layer, such as a heat resistant layer, a rust preventing layer, a chromate treatment layer, a silane coupling treatment layer, and a resin layer, on the surface thereof, the “surface on the side of the heat generating component” or the “surface” of the metal material for heat radiation means the outermost surface thereof after providing the surface treatment layer.

The surface of the metal material for heat radiation on the side of the heat generating component preferably has a surface roughness Sa (i.e., the arithmetic average roughness of the surface) of 0.13 μm or more. When the surface roughness Sa of the surface of the metal material for heat radiation on the side of the heat generating component is less than 0.13 μm, there may be a possibility that the heat radiation property of the heat from the heat generating component becomes inferior. The surface roughness Sa of the surface of the metal material for heat radiation on the side of the heat generating component is more preferably 0.20 μm or more, further preferably 0.25 μm or more, and still further preferably 0.30 μm or more, and is typically from 0.1 to 1.0 μm, and more typically from 0.1 to 0.9 μm. Further, the upper limit of the surface roughness Sa of the surface of the metal material for heat radiation on the side of the heat generating component is not particularly limited, but is typically 1.0 μm or less, for example, 0.9 μm or less

The surface of the metal material for heat radiation on the side of the heat generating component preferably has a surface roughness Sku (i.e., the kurtosis of the surface height distribution; kurtosis number) of 6 or more. When the Sku of the surface of the metal material for heat radiation on the side of the heat generating component is less than 6, there may be a possibility that the heat radiation property of the heat from the heat generating component becomes inferior. The Sku of the surface of the metal material for heat radiation on the side of the heat generating component is more preferably 9 or more, further preferably 10 or more, still further preferably 40 or more, and still further preferably 60 or more, and is typically from 3 to 200, and more typically from 4 to 180. Further, the upper limit of the Sku of the surface of the metal material for heat radiation on the side of the heat generating component is not particularly limited, but is typically 200 or less, for example, 180 or less.

The surface of the metal material for heat radiation on the side of the heat generating component preferably has a color difference ΔL based on JIS 28730 satisfying ΔL≦−40. When the color difference ΔL on the surface of the metal material for heat radiation on the side of the heat generating component is controlled to satisfy ΔL≦−40, radiation heat, convection heat, and the like generated from the heat generating component can be favorably absorbed. The color difference ΔL preferably satisfies ΔL≦−45, more preferably ΔL≦−50, further preferably ΔL≦−55, still further preferably ΔL≦−58, still further preferably ΔL≦−60, still further preferably ΔL≦−65, still further preferably ΔL≦−68, and still further preferably ΔL≦−70. The lower limit of the ΔL may not be necessarily determined, but may satisfy, for example, ΔL≦−90, ΔL≦−88, ΔL≧−85, ΔL≧−83, ΔL≧−80, ΔL≦−78, or ΔL≦−75. The color difference ΔL based on JIS 28730 of the surface can be measured with a colorimeter, MiniScan XE Plus, produced by Hunter Associates Laboratory, Inc.

The color difference ΔL can be controlled, for example, by using a copper material as a substrate of the metal material for heat radiation, and forming roughening particles on the surface of the copper material. The color difference ΔL can be achieved in such a manner that primary roughening particles are formed by using an electrolytic solution containing at least one element of copper, nickel, and cobalt at an increased current density (for example, from 30 to 50 A/dm²) for a shortened treatment time (for example, from 0.5 to 1.5 seconds), and thereon secondary roughening particles are formed at a high current density (for example, from 20 to 40 A/dm²) for a short treatment time (for example, from 0.1 to 0.5 seconds).

A surface treatment layer may be provided on the surface of the metal material for heat radiation on the side of the heat generating component. The surface treatment layer may contain one or more layers selected from the group consisting of a roughening treatment layer, a heat resistant layer, a rust preventing layer, a chromate treatment layer, a silane coupling treatment layer, a plated layer, and a resin layer.

A roughening treatment for forming the roughening treatment layer may be performed, for example, by forming roughening particles with copper or a copper alloy. The roughening treatment may be a fine treatment. The roughening treatment layer may be a layer formed of an elemental substance of any one of copper, nickel, cobalt, phosphorus, tungsten, arsenic, molybdenum, chromium, and zinc, or an alloy containing one or more of them, or the like. After forming the roughening particles with copper or a copper alloy, a roughening treatment may be further performed to provide secondary particles or tertiary particles with, for example, an elemental substance or an alloy of nickel, cobalt, copper, or zinc. Thereafter, a heat resistant layer or a rust preventing layer may be formed with, for example, an elemental substance or an alloy of nickel, cobalt, copper, or zinc, and further on the surface thereof, such treatments as a chromate treatment, a silane coupling treatment, and the like may be performed. In alternative, without a roughening treatment performed, a plated layer may be formed, or a heat resistant layer or a rust preventing layer may be formed with, for example, an elemental substance or an alloy of nickel, cobalt, copper, or zinc, and further on the surface thereof, such a treatment as a chromate treatment, a silane coupling treatment, and the like may be performed. Accordingly, one or more layer selected from the group consisting of a heat resistant layer, a rust preventing layer, a chromate treatment layer, a silane coupling treatment layer, a plated layer, and a resin layer may be formed on the surface of the roughening treatment layer. The heat resistant layer, the rust preventing layer, the chromate treatment layer, the silane coupling treatment layer, the plated layer, and the resin layer each may be formed of a plurality of layers (for example, two or more layers, or three or more layers). The plated layer can be formed by wet plating, such as electro plating, electroless plating, and dip plating, or dry plating, such as sputtering, CVD, and PDV.

The chromate treatment layer means a layer treated with a liquid containing chromic anhydride, chromic acid, dichromic acid, a chromate salt, or a dichromate salt. The chromate treatment layer may contain such elements as iron, nickel, molybdenum, zinc, tantalum, copper, aluminum, phosphorus, tungsten, tin, arsenic, titanium, and the like (which may be in any form, for example, a metal, an alloy, an oxide, a nitride, and a sulfide). Specific examples of the chromate treatment layer include a chromate treatment layer treated with an aqueous solution of chromic anhydride or potassium dichromate, and a chromate treatment layer treated with a treatment liquid containing chromic anhydride or potassium dichromate and zinc.

The heat resistant layer and the rust preventing layer used may be a known heat resistant layer and a known rust preventing layer. For example, the heat resistant layer and/or the rust preventing layer may be a layer containing one or more element selected from the group consisting of nickel, zinc, tin, cobalt, molybdenum, copper, tungsten, phosphorus, arsenic, chromium, vanadium, titanium, aluminum, gold, silver, a platinum group element, iron, and tantalum, and may be a metal layer or an alloy layer formed of one or more element selected from the group consisting of nickel, zinc, tin, cobalt, molybdenum, copper, tungsten, phosphorus, arsenic, chromium, vanadium, titanium, aluminum, gold, silver, a platinum group element, iron, and tantalum. The heat resistant layer and/or the rust preventing layer may contain an oxide, a nitride, or a silicide of one or more element selected from the group consisting of nickel, zinc, tin, cobalt, molybdenum, copper, tungsten, phosphorus, arsenic, chromium, vanadium, titanium, aluminum, gold, silver, a platinum group element, iron, and tantalum. The heat resistant layer and/or the rust preventing layer may be a layer containing a nickel-zinc alloy. The heat resistant layer and/or the rust preventing layer may be a nickel-zinc alloy layer. The heat resistant layer and/or the rust preventing layer may be a layer of an organic material. The layer of an organic material may contain one or more organic material selected from the group consisting of a nitrogen-containing organic compound, a sulfur-containing organic compound, and a carboxylic acid. The nitrogen-containing organic compound used is specifically preferably a triazole compound having a substituent, such as 1,2,3-benzotriazole, carboxybenzotriazole, N′,N′-bis(benzotriazolylmethyl)urea, 1H-1,2,4-triazole, and 3-amino-1H-1,2,4-triazole. The sulfur-containing compound used is preferably mercaptobenzothiazole, sodium 2-mercaptobenzothiazole, thiocyanuric acid, or 2-benzimidazolthiol. The carboxylic acid used is particularly preferably a monocarboxylic acid, and therein oleic acid, linoleic acid, linolenic acid, or the like are preferably used. The heat resistant layer and/or the rust preventing layer may be a known organic rust preventing film containing carbon.

A silane coupling agent used for the silane coupling treatment may be a known silane coupling agent, and examples thereof used include an amino silane coupling agent, an epoxy silane coupling agent, and a mercapto silane coupling agent. Examples of the silane coupling agent used also include vinyltrimethoxysilane, vinylphenyltrimethoxysilane, γ-methacryloxypropyltrimethoxysilane, γ-glycidoxypropyltrimethoxysilane, 4-glycidylbutyltrimethoxysilane, γ-aminopropyltriethoxysilane, N-β-(aminoethyl)-γ-aminopropyltrimethoxysilane, N-3-(4-(3-aminopropoxy)butoxy)propyl-3-aminopropyltrimethoxysilane, imidazole silane, triazine silane, and γ-mercaptopropyltrimethoxysilane.

The resin layer used may be a layer containing a known resin. The resin layer is preferably a resin layer containing a resin that radiates heat. The resin used in the resin layer preferably has a high radiation factor. The resin layer used may be a known heat radiation sheet. The resin layer used may be a resin layer containing one or more selected from the group consisting of a silicone resin, an acrylic resin, a urethane resin, ethylene-propylene-diene rubber, synthetic rubber, an epoxy resin, a fluorine resin, a polyimide resin, a liquid crystal polymer, a polyamide resin, a silicone oil, a silicone grease, and a silicone oil compound. The resin layer may contain one or more selected from the group consisting of a metal, ceramics, an inorganic material, and an organic material, as a filler. The metal may be any one metal selected from the group consisting of Ag, Cu, Ni, Zn, Au, Al, a platinum group element, and Fe, or an alloy containing any one of them. The ceramics may be one or more selected from the group consisting of an oxide, a nitride, a silicide, and a carbide. The oxide may contain one or more selected from the group consisting of aluminum oxide, silicon oxide, zinc oxide, copper oxide, iron oxide, zirconium oxide, beryllium oxide, titanium oxide, and nickel oxide. The nitride may contain one or more selected from the group consisting of boron nitride, aluminum nitride, silicon nitride, and titanium nitride. The silicide may contain one or more selected from the group consisting of silicon carbide, molybdenum silicide (e.g., MoSi₂ and Mo₂Si₃), tungsten silicide (e.g., WSi₂ and W₅Si₃), tantalum silicide (e.g., TaSi₂), chromium silicide, and nickel silicide. The carbide may contain one or more selected from the group consisting of silicon carbide, tungsten carbide, calcium carbide, and boron carbide. The inorganic material may contain one or more selected from the group consisting of graphite, carbon nanotubes, fullerene, diamond, graphene, and ferrite.

The surface of the metal material for heat radiation on the side of the heat generating component preferably has a radiation factor of 0.03 or more. When the radiation factor of the surface of the metal material for heat radiation on the side of the heat generating component is 0.03 or more, the heat from the heat generating component can be favorably radiated. The radiation factor of the surface of the metal material for heat radiation on the side of the heat generating component is more preferably 0.04 or more, more preferably 0.05 or more, more preferably 0.06 or more, more preferably 0.092 or more, more preferably 0.10 or more, further preferably 0.123 or more, further preferably 0.154 or more, further preferably 0.185 or more, further preferably 0.246 or more, preferably 0.3 or more, preferably 0.4 or more, preferably 0.5 or more, preferably 0.6 or more, and preferably 0.7 or more.

The upper limit of the radiation factor of the surface of the metal material for heat radiation on the side of the heat generating component may not be necessarily determined, and is typically 1 or less, more typically 0.99 or less, more typically 0.95 or less, more typically 0.90 or less, more typically 0.85 or less, and more typically 0.80 or less. When the radiation factor of the surface of the metal material for heat radiation on the side of the heat generating component is 0.90 or less, the productivity may be enhanced.

The metal material for heat radiation may be a metal material for heat radiation containing one or more surfaces, at least one of the surfaces satisfies one or more of the following items (1) to (5), and the metal material for heat radiation is to be adhered with a graphite sheet and to be used:

(1) the surface having a color difference ΔL based on JIS 28730 satisfying ΔL≦−40;

(2) the surface having a radiation factor of 0.03 or more;

(3) the surface having a surface roughness Sz of 5 μm or more measured with a laser microscope with laser light having a wavelength of 405 nm;

(4) the surface having a surface roughness Sa of 0.13 μm or more measured with a laser microscope with laser light having a wavelength of 405 nm; and

(5) the surface having a surface roughness Sku of 6 or more measured with a laser microscope with laser light having a wavelength of 405 nm.

The color difference ΔL based on JIS 28730, the radiation factor, and the surface roughnesses Sz, Sa, and Sku measured with a laser microscope with laser light having a wavelength of 405 nm of the surface of the metal material for heat radiation are preferably controlled to the ranges of the color difference ΔL based on JIS 28730, the radiation factor, and the surface roughnesses Sz, Sa, and Sku measured with a laser microscope with laser light having a wavelength of 405 nm of the surface of the metal material for heat radiation on the side of the heat generating component, respectively. The metal material for heat radiation can be adhered with a graphite sheet and can be used as a heat radiating member.

In the structure having a metal material for heat radiation of the invention, the heat radiating member may further contain a substance having thermal conductivity on a face of the heat radiating member on the side of the heat generating component. According to the constitution, the heat from the heat generating component can be favorably radiated.

The substance having thermal conductivity used may be a substance containing one or more selected from the group consisting of a resin, a metal, ceramics, an inorganic material, and an organic material. The resin used may be one or more selected from the group consisting of a silicone resin, an acrylic resin, a urethane resin, ethylene-propylene-diene rubber, synthetic rubber, natural rubber, an epoxy resin, a polyethylene resin, a polyphenylene sulfide (PPS) resin, a polybutylene terephthalate (PBT) resin, a fluorine resin, a polyimide resin, a polycarbonate resin, a liquid crystal polymer, a polyamide resin, a silicone oil, a silicone grease, and a silicone oil compound. The resin may contain one or more selected from the group consisting of a metal, ceramics, an inorganic material, and an organic material, as a filler. The metal, the ceramics, the inorganic material, and the organic material may be the metal, the ceramics, the inorganic material, and the organic material contained in the resin layer. The form of the metal may be a bulk form, a particle form, a strand form, a flake form, or a mesh form.

The substance having thermal conductivity preferably has a thermal conductivity of 0.5 W/(m·K) or more, preferably 1 W/(m·K) or more, preferably 2 W/(m·K) or more, preferably 3 W/(m·K) or more, preferably 5 W/(m·K) or more, preferably 10 W/(m·K) or more, more preferably 20 W/(m·K) or more, more preferably 30 W/(m·K) or more, and further preferably 35 W/(m·K) or more. The upper limit of the thermal conductivity of the substance is not particularly limited, and for example, 4,000 W/(m·K) or less, 3,000 W/(m·K) or less, or 2,500 W/(m·K) or less. The thermal conductivity of the substance having thermal conductivity is preferably the thermal conductivity in the direction in parallel to the thickness direction of the substance. The thickness direction of the substance having thermal conductivity herein is the direction in parallel to the thickness direction of the metal material for heat radiation.

A printed wiring board can be produced by using the structure having a metal material for heat radiation of the invention, and a printed circuit board may be produced by mounting electric components on the printed wiring board. An electronic apparatus may be produced by using the printed circuit board, and an electronic apparatus may be produced by using the printed circuit board having electronic components mounted thereon. The structure having a metal material for heat radiation of the invention may be used for heat radiation of a heat radiating component of various electronic apparatuses, such as a display, a IC chip, a capacitor, an inductor, a connector, a terminal, a memory, an LSI, a chassis, a CPU, a circuit, and an integrated circuit. For example, the structure having a metal material for heat radiation can be used for heat radiation of an application processor or the like of a mobile equipment, such as a smartphone and a tablet PC, as the heat radiating component.

### EXAMPLES

### 1. Preparation of Heat Radiating Material

As a heat radiating material, a graphite sheet having a thickness of 25 μm and the following metal materials for heat radiation A to E were prepared.

### Metal Material for Heat Radiation A

Metal material: copper substrate (rolled copper foil, a tough pitch copper defined in JIS H3100, alloy number: C1100, obtained by rolling with an oil film equivalent amount of 25,000 in the final cold rolling in the production of the rolled copper foil)

The oil film equivalent amount is shown by the following expression.

(oil film equivalent amount)=((viscosity of rolling oil (cSt))×((rolling speed (mpm))+(roll peripheral velocity (mpm)))/((bite angle of roll (rad))×(yield stress of material (kg/mm²)))

The viscosity of rolling oil (cSt) is the kinetic viscosity thereof at 40° C.

For achieving an oil film equivalent amount of 25,000, a known method may be used, for example, a rolling oil having high viscosity is used, or the rolling speed is increased.

Surface treatment: electroplating treatment

Plating solution conditions:

Cu concentration: 9 g/L, Co concentration: 8 g/L, Ni concentration: 8 g/L

pH: 3.5

Temperature: 35° C.

Current density: 33 A/dm²

Plating time: 0.5 seconds×4

Thickness: 35 μm

Color difference ΔL of the surface of the metal material for heat radiation on the side of the heat generating component: −62.4

Surface roughnesses of the surface of the metal material for heat radiation on the side of the heat generating component, Sz: 11.4 μm, Sa: 0.33 μm, Sku: 9.21

### Metal Material for Heat Radiation B

Metal material: copper substrate (rolled copper foil, having a composition of a tough pitch copper defined in JIS H3100, alloy number: C1100, having Ag added thereto in an amount of 180 ppm by mass, obtained by ordinary rolling with an oil film equivalent amount of 25,000 in the final cold rolling in the production of the rolled copper foil)

Surface treatment: electroplating treatments (performed (1) and (2) in this order)

Plating solution conditions (1):

Cu concentration: 10 g/L, Sulfuric acid concentration: 20 g/L

pH: 1.0

Temperature: 26° C.

Current density: 44 A/dm²

Plating time: 0.7 seconds×2

Current density: 4 A/dm²

Plating time: 1.5 seconds×2

Plating solution conditions (2):

Cu concentration: 8 g/L, Co concentration: 8 g/L, Ni concentration: 8 g/L

pH: 3.5

Temperature: 35° C.

Current density: 30 A/dm²

Plating time: 0.5 seconds×2

Thickness: 35 μm

Color difference ΔL of the surface of the metal material for heat radiation on the side of the heat generating component: −53.3

Surface roughnesses of the surface of the metal material for heat radiation on the side of the heat generating component, Sz: 24.5 μm, Sa: 0.42 μm, Sku: 20.8

Metal Material for Heat Radiation C

Metal material: copper substrate (rolled copper foil, having a composition of an oxygen-free copper defined in JIS H3100, alloy number: C1020, having Ag added thereto in an amount of 100 ppm by mass, obtained by ordinary rolling with an oil film equivalent amount of 25,000 in the final cold rolling in the production of the rolled copper foil)

Surface treatment: electroplating treatments (performed (1) and (2) in this order)

Plating solution conditions (1):

Cu concentration: 10 g/L, Sulfuric acid concentration: 20 g/L

pH: 1.0

Temperature: 26° C.

Current density: 45 A/dm²

Plating time: 0.8 seconds×2

Current density: 4 A/dm²

Plating time: 2.0 seconds×2

Plating solution conditions (2):

Cu concentration: 8 g/L, Co concentration: 8 g/L, Ni concentration: 8 g/L

pH: 3.5

Temperature: 35° C.

Current density: 31 A/dm²

Plating time: 0.6 seconds×2

Thickness: 70 μm

Color difference ΔL of the surface of the metal material for heat radiation on the side of the heat generating component: −54.2

Surface roughnesses of the surface of the metal material for heat radiation on the side of the heat generating component, Sz: 25.1 μm, Sa: 0.43 μm, Sku: 21.4

### Metal Material for Heat Radiation D

Metal material: copper substrate (rolled copper foil, having a composition of an oxygen-free copper defined in JIS H3100, alloy number: C1020, having Ag added thereto in an amount of 100 ppm by mass, obtained by ordinary rolling with an oil film equivalent amount of 25,000 in the final cold rolling in the production of the rolled copper foil)

Surface treatment: electroplating treatments (performed (1) and (2) in this order)

Plating solution conditions (1):

Cu concentration: 10 g/L, Sulfuric acid concentration: 20 g/L

pH: 1.0

Temperature: 26° C.

Current density: 46 A/dm²

Plating time: 0.8 seconds×2

Current density: 6 A/dm²

Plating time: 2.0 seconds×2

Plating solution conditions (2):

Cu concentration: 8 g/L, Co concentration: 8 g/L, Ni concentration: 8 g/L, P concentration: 300 ppm

pH: 3.5

Temperature: 35° C.

Current density: 32 A/dm²

Plating time: 0.5 seconds×2

Thickness: 100 μm

Color difference ΔL of the surface of the metal material for heat radiation on the side of the heat generating component: −55.3

Surface roughnesses of the surface of the metal material for heat radiation on the side of the heat generating component, Sz: 26.4 μm, Sa: 0.45 μm, Sku: 22.3

### Metal Material for Heat Radiation E

Metal material: copper substrate (rolled copper foil, having a composition of a tough pitch copper defined in JIS H3100, alloy number: C1100, having Ag added thereto in an amount of 180 ppm by mass, obtained by ordinary rolling with an oil film equivalent amount of 25,000 in the final cold rolling in the production of the rolled copper foil)

Surface treatment: electroplating treatments (performed (1) and (2) in this order)

Plating solution conditions (1):

Cu concentration: 10 g/L, Sulfuric acid concentration: 20 g/L

pH: 1.0

Temperature: 26° C.

Current density: 55 A/dm²

Plating time: 2.0 seconds×4

Current density: 4 A/dm²

Plating time: 1.5 seconds×2

Plating solution conditions (2):

Cu concentration: 8 g/L, Co concentration: 8 g/L, Ni concentration: 8 g/L

pH: 3.5

Temperature: 35° C.

Current density: 40 A/dm²

Plating time: 0.9 seconds×5

Thickness: 35 μm

Color difference ΔL of the surface of the metal material for heat radiation on the side of the heat generating component: −89.3

Surface roughnesses of the surface of the metal material for heat radiation on the side of the heat generating component, Sz: 42.3 μm, Sa: 0.62 μm, Sku: 25.7

The electroplated surfaces of the metal materials for heat radiation A to E were subjected to the heat resistant plating treatment and the rust preventing plating treatment below.

### Heat Resistant Plating Treatment

Ni concentration: 12 g/L, Co concentration: 3 g/L

pH: 2.0

Temperature: 50° C.

Current density: 15 A/dm²

Plating time: 0.4 seconds×2

### Rust Preventing Plating Treatment

Cr concentration: 3.0 g/L, Zn concentration: 3.0 g/L

pH: 2.0

Temperature: 55° C.

Current density: 2.0 A/dm²

Plating time: 0.5 seconds×2

### Color Difference

The surfaces of the metal materials for heat radiation on the side of the heat generating component were evaluated for the color difference in the following manner.

The color difference of the surface of the metal material for heat radiation on the side of the heat generating component with respect to the object color of the white plate (assuming D65 as the light source and 10° for the view field, the white plate had tristimulus values of the X₁₀Y₁₀Z₁₀ colorimetric system (JIS 28701 1999) of X₁₀=80.7, Y₁₀=85.6, Z₁₀=91.5, and the white plate had an object color of the L*a*b* colorimetric system of L*=94.14, a*=−0.90, b*=0.24) as the standard color was measured according to JIS H8730 with a colorimeter, MiniScan XE Plus, produced by Hunter Associates Laboratory, Inc. In the colorimeter, the color difference is calibrated with ΔE*ab=0 as the measured value of the color difference of the white plate, and ΔE*ab=94.14 as the measured value of the color difference measured with the measurement port covered with a black bag (light trap). Herein, the color difference ΔE*ab is defined as 0 for the white plate and 94.14 for black color. The color difference ΔE*ab according to JIS 28730 of a microscopic area, such as a surface of a copper circuit, can be measured with a known measurement equipment, such as a microscopic area spectrophotometer (Model: VSS 400 or the like), produced by Nippon Denshoku Industries Co., Ltd., and a microscopic area spectrophotometer (Model: SC-50μ or the like), produced by Suga Test Instruments Co., Ltd.

### Sz, Sa, and Sku of Surface

The surfaces of the metal materials for heat radiation on the side of the heat generating component were evaluated for Sz, Sa, and Sku in the following manner.

Sz, Sa, and Sku of the surface of the metal material for heat radiation were measured according to ISO 25178 with a laser microscope, OLS 4000 (LEXT OLS 4000), produced by Olympus Corporation. An area of approximately 200 μm×200 μm (specifically 40,106 μm²) was measured by using an objective lens of a magnification of 50 of the laser microscope, and Sz, Sa, and Sku were calculated. In the case where the measurement surface of the measurement result became a curved surface (not a flat surface) in the measurement with the laser microscope, Sz, Sa, and Sku were calculated after performing the plane correction. The environment temperature for the measurement of Sz, Sa, and Sku with the laser microscope was from 23 to 25° C.

### 2. Production of Structure, Structure Having Graphite for Heat Radiation, and Structure Having Metal Material for Heat Radiation

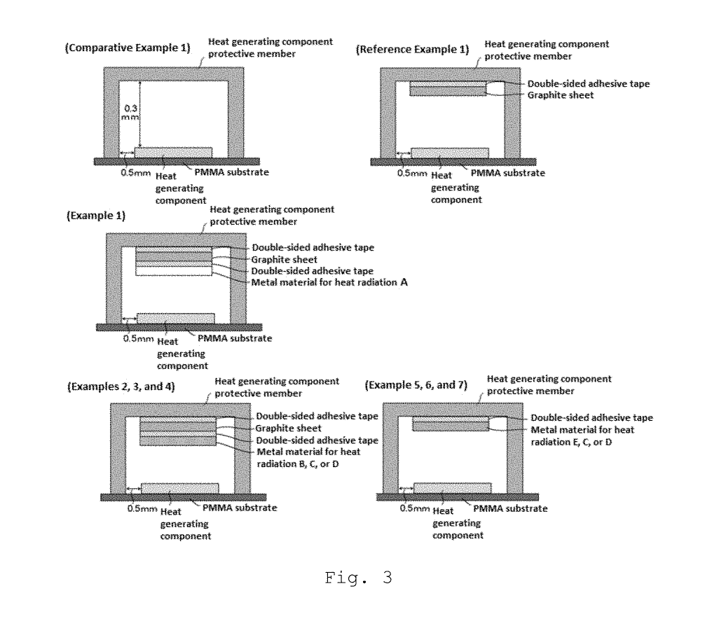

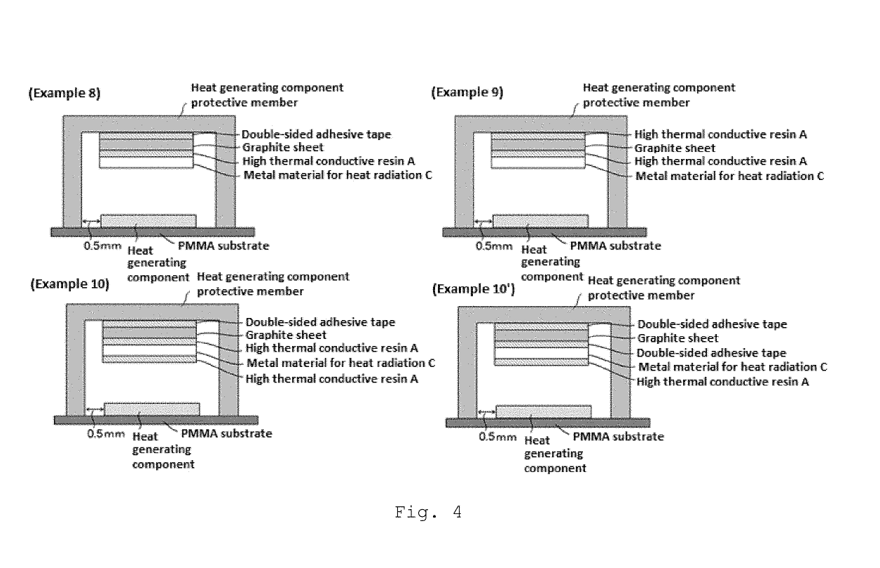

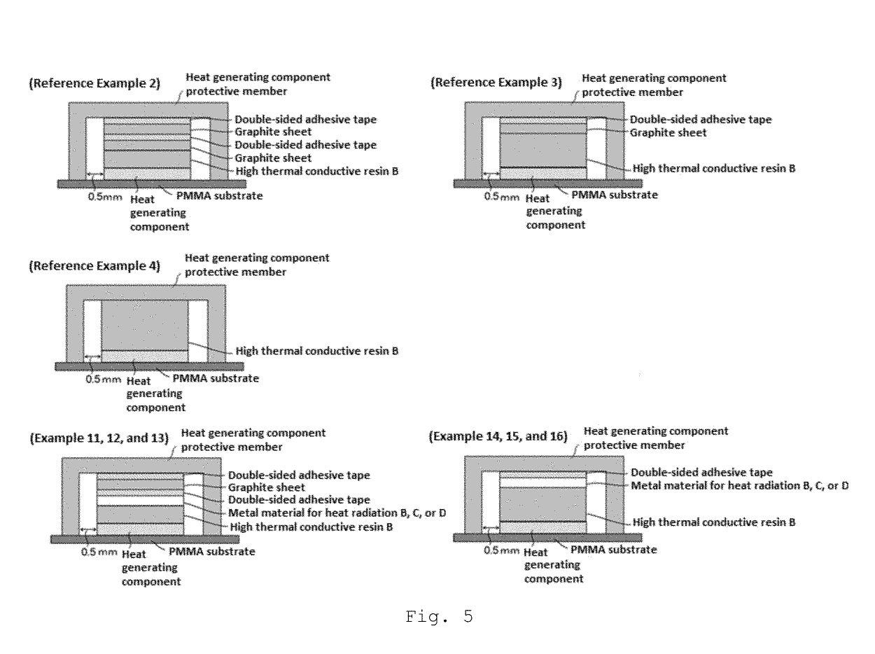

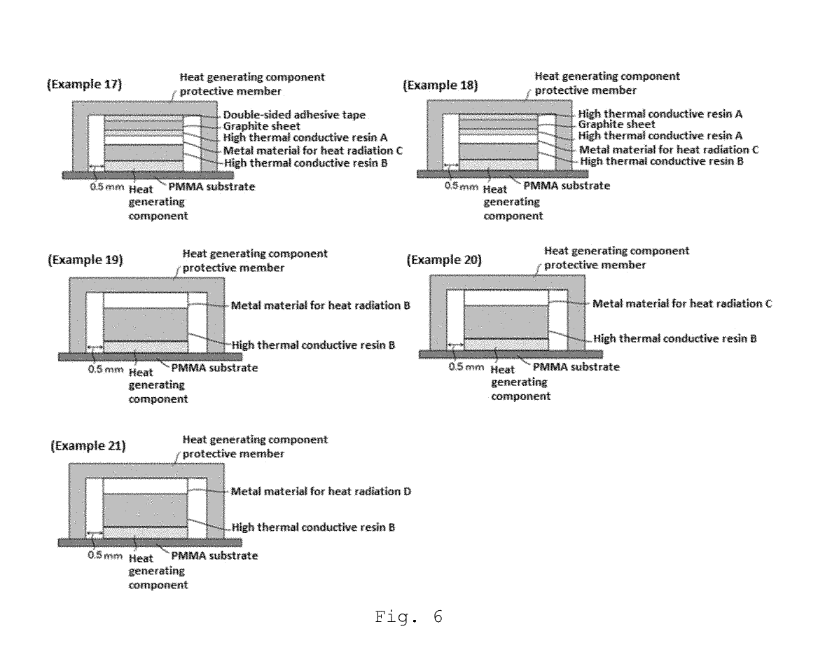

Subsequently, as shown in FIGS. 3 to 6, various structures, structures having graphite for heat radiation, and structures having a metal material for heat radiation were produced.

A polymethyl methacrylate (PMMA) substrate having a size of length×width×height=25 mm×50 mm×1 mm was prepared. A heat generating component (a heat generating component containing heating wire embedded in a resin, corresponding to an IC chip) having a size of length×width×height=15 mm×15 mm×1 mm was placed on the center of the surface of the substrate, and covered with a heat generating component protective member having a thickness of 200 μm formed of a stainless steel, and a heat radiating material was provided on the surface of the heat generating component protective member on the side of the heat generating component, thereby producing a shield box (i.e., a structures, a structure having graphite for heat radiation, or a structure having a metal material for heat radiation). As shown in Comparative Example 1 in FIG. 3 as a representative example, the distance from the upper surface of the heat generating component to the lower surface of the heat generating component protective member was 0.3 mm, and the distance from the side surface of the heat generating member to the heat generating component protective member was 0.5 mm.

(1) Structure of Comparative Example 1

The structure of Comparative Example 1 had a constitution having no heat radiating material used.

(2) Structure Having Graphite for Heat Radiation of Reference Example 1

In the structure having graphite for heat radiation of Reference Example 1, a graphite sheet having a thickness of 25 μm and a double-sided adhesive tape using an acrylic adhesive having a thickness of 10 μm were provided and fixed as a heat radiating material to the surface of the heat radiating component protective member on the side of the heat generating component in this order from the side of the heat generating component.

(3) Structure Having Metal Material for Heat Radiation of Example 1

In the structure having a metal material for heat radiation of Example 1, the metal material for heat radiation A, a double-sided adhesive tape using an acrylic adhesive having a thickness of 10 μm, a graphite sheet having a thickness of 25 μm, and a double-sided adhesive tape using an acrylic adhesive having a thickness of 10 μm were provided and fixed as a heat radiating material to the surface of the heat radiating component protective member on the side of the heat generating component in this order from the side of the heat generating component.

(4) Structures Having Metal Material for Heat Radiation of Examples 2, 3, and 4

In the structures having a metal material for heat radiation of Examples 2, 3, and 4, the metal material for heat radiation B (Example 2), the metal material for heat radiation C (Example 3), or the metal material for heat radiation D (Example 4), a double-sided adhesive tape using an acrylic adhesive having a thickness of 10 μm, a graphite sheet having a thickness of 25 μm, and a double-sided adhesive tape using an acrylic adhesive having a thickness of 10 μm were provided and fixed as a heat radiating material to the surface of the heat radiating component protective member on the side of the heat generating component in this order from the side of the heat generating component.

(5) Structures Having Metal Material for Heat Radiation of Examples 5, 6, and 7

In the structures having a metal material for heat radiation of Examples 5, 6, and 7, the metal material for heat radiation E (Example 5), the metal material for heat radiation C (Example 6), or the metal material for heat radiation D (Example 7), and a double-sided adhesive tape using an acrylic adhesive having a thickness of 10 μm were provided and fixed as a heat radiating material to the surface of the heat radiating component protective member on the side of the heat generating component in this order from the side of the heat generating component.

(6) Structure Having Metal Material for Heat Radiation of Example 8

In the structure having a metal material for heat radiation of Example 8, the metal material for heat radiation C, a high thermal conductive resin A (a silicone oil compound for heat radiation, Model No. G-776, produced by Shin-Etsu Chemical Co., Ltd.) having a thickness of 10 μm, a graphite sheet having a thickness of 25 μm, and a double-sided adhesive tape using an acrylic adhesive having a thickness of 10 μm were provided and fixed as a heat radiating material to the surface of the heat radiating component protective member on the side of the heat generating component in this order from the side of the heat generating component.

(7) Structure Having Metal Material for Heat Radiation of Example 9

In the structure having a metal material for heat radiation of Example 9, the metal material for heat radiation C, the high thermal conductive resin A having a thickness of 10 μm, a graphite sheet having a thickness of 25 μm, and the high thermal conductive resin A having a thickness of 10 μm were provided and fixed as a heat radiating material to the surface of the heat radiating component protective member on the side of the heat generating component in this order from the side of the heat generating component.

(8) Structure Having Metal Material for Heat Radiation of Example 10

In the structure having a metal material for heat radiation of Example 10, the high thermal conductive resin A having a thickness of 10 μm, the metal material for heat radiation C, the high thermal conductive resin A having a thickness of 10 μm, a graphite sheet having a thickness of 25 μm, and a double-sided adhesive tape using an acrylic adhesive having a thickness of 10 μm were provided and fixed as a heat radiating material to the surface of the heat radiating component protective member on the side of the heat generating component in this order from the side of the heat generating component.

(9) Structure Having Metal Material for Heat Radiation of Example 10′

In the structure having a metal material for heat radiation of Example 10′, the high thermal conductive resin A having a thickness of 10 μm, the metal material for heat radiation C, a double-sided adhesive tape using an acrylic adhesive having a thickness of 10 μm, a graphite sheet having a thickness of 25 μm, and a double-sided adhesive tape using an acrylic adhesive having a thickness of 10 μm were provided and fixed as a heat radiating material to the surface of the heat radiating component protective member on the side of the heat generating component in this order from the side of the heat generating component.

(10) Structure Having Graphite for Heat Radiation of Reference Example 2

In the structure having graphite for heat radiation of Reference Example 2, a high thermal conductive resin B (a silicone resin, Denka Thermally Conductive Spacer, Grease Type, grade: GFC-L1, produced by Denka Co., Ltd.) having a thickness of 230 μm, a graphite sheet having a thickness of 25 μm, a double-sided adhesive tape using an acrylic adhesive having a thickness of 10 μm, a graphite sheet having a thickness of 25 μm, and a double-sided adhesive tape using an acrylic adhesive having a thickness of 10 μm were provided and fixed as a heat radiating material to the surface of the heat radiating component protective member on the side of the heat generating component in this order from the side of the heat generating component. The high thermal conductive resin B was provided direct contact with the heat generating component with no space to the heat generating component.

(11) Structure Having Graphite for Heat Radiation of Reference Example 3

In the structure having graphite for heat radiation of Reference Example 3, the high thermal conductive resin B having a thickness of 265 μm, a graphite sheet having a thickness of 25 μm, and a double-sided adhesive tape using an acrylic adhesive having a thickness of 10 μm were provided and fixed as a heat radiating material to the surface of the heat radiating component protective member on the side of the heat generating component in this order from the side of the heat generating component. The high thermal conductive resin B was provided direct contact with the heat generating component with no space to the heat generating component.

(12) Structure of Reference Example 4

In the structure of Reference Example 4, the high thermal conductive resin B was provided between the surface of the heat generating component protective member on the side of the heat generating component and the surface of the heat generating component with no space.

(13) Structures Having Metal Material for Heat Radiation of Examples 11 to 13

In the structures having a metal material for heat radiation of Examples 11 to 13, the metal material for heat radiation B (Example 11), the metal material for heat radiation C (Example 12), or the metal material for heat radiation D (Example 13), a double-sided adhesive tape using an acrylic adhesive having a thickness of 10 μm, a graphite sheet having a thickness of 25 μm, and a double-sided adhesive tape using an acrylic adhesive having a thickness of 10 μm were provided and fixed as a heat radiating material to the surface of the heat radiating component protective member on the side of the heat generating component in this order from the side of the heat generating component. Furthermore, the high thermal conductive resin B was provided between the metal materials for heat radiation B to D and the heat generating component with no space.

(14) Structures Having Metal Material for Heat Radiation of Examples 14 to 16

In the structures having a metal material for heat radiation of Examples 14 to 16, the metal material for heat radiation B (Example 14), the metal material for heat radiation C (Example 15), or the metal material for heat radiation D (Example 16), and a double-sided adhesive tape using an acrylic adhesive having a thickness of 10 μm were provided and fixed as a heat radiating material to the surface of the heat radiating component protective member on the side of the heat generating component in this order from the side of the heat generating component. Furthermore, the high thermal conductive resin B was provided between the metal materials for heat radiation B to D and the heat generating component with no space.

(15) Structure Having Metal Material for Heat Radiation of Example 17

In the structure having a metal material for heat radiation of Example 17, the metal material for heat radiation C, the high thermal conductive resin A having a thickness of 10 μm, a graphite sheet having a thickness of 25 μm, and a double-sided adhesive tape using an acrylic adhesive having a thickness of 10 μm were provided and fixed as a heat radiating material to the surface of the heat radiating component protective member on the side of the heat generating component in this order from the side of the heat generating component. Furthermore, the high thermal conductive resin B was provided between the metal material for heat radiation C and the heat generating component with no space.

(16) Structure Having Metal Material for Heat Radiation of Example 18

In the structure having a metal material for heat radiation of Example 18, the metal material for heat radiation C, the high thermal conductive resin A having a thickness of 10 μm, a graphite sheet having a thickness of 25 μm, and the high thermal conductive resin A having a thickness of 10 μm were provided and fixed as a heat radiating material to the surface of the heat radiating component protective member on the side of the heat generating component in this order from the side of the heat generating component. Furthermore, the high thermal conductive resin B was provided between the metal material for heat radiation C and the heat generating component with no space.

(17) Structure Having Metal Material for Heat Radiation of Example 19

In the structure having a metal material for heat radiation of Example 19, the high thermal conductive resin B and the metal material for heat radiation B were provided and fixed as a heat radiating material to the surface of the heat radiating component protective member on the side of the heat generating component in this order from the side of the heat generating component. The high thermal conductive resin B was provided between the metal material for heat radiation B and the heat generating component with no space.

(18) Structure Having Metal Material for Heat Radiation of Example 20

In the structure having a metal material for heat radiation of Example 20, the high thermal conductive resin B and the metal material for heat radiation C were provided and fixed as a heat radiating material to the surface of the heat radiating component protective member on the side of the heat generating component in this order from the side of the heat generating component. The high thermal conductive resin B was provided between the metal material for heat radiation C and the heat generating component with no space.

(19) Structure Having Metal Material for Heat Radiation of Example 21

In the structure having a metal material for heat radiation of Example 21, the high thermal conductive resin B and the metal material for heat radiation D were provided and fixed as a heat radiating material to the surface of the heat radiating component protective member on the side of the heat generating component in this order from the side of the heat generating component. The high thermal conductive resin B was provided between the metal material for heat radiation D and the heat generating component with no space.

### Measurement of Reflectance

The aforementioned specimens were measured for reflectances to the wavelengths of light under the following condition. The measurement was performed twice with the measurement direction changed by 90° within the measurement plane of the specimen.

Measurement equipment: IFS-66v (FT-IR with vacuum optical system, produced by Bruker Corporation)

Light source: Grover (SiC)

Detector: MCT (HgCdTe)

Beam splitter: Ge/KBr

Measurement condition: resolution: 4 cm⁻¹

Cumulated number: 512

Zero filling: twice

Apodization: triangle

Measurement range: 5,000 to 715 cm⁻¹ (light wavelength: 2 to 14 μm)

Measurement temperature: 25° C.

Auxiliary device: integrating sphere for measuring

transmittance and reflectance

Port diameter: 10 mm

Repetitive accuracy: ca.±1%

Measurement Condition for Reflectance:
Incident angle: 10°
Reference specimen: diffuse gold (Infragold-LF Assembly)
Specular cup (specular component removing device): not provided

### Radiation Factor

Light incident on the specimen surface is reflected and transmitted, and also is absorbed by the interior thereof. The absorbance (a) (=radiation factor (ε)), the reflectance (r), and the transmittance (t) satisfy the following expression.

ε+r+t=1 (A)

The radiation factor (ε) can be obtained from the reflectance and the transmittance according to the following expression.

ε=1−r−t (B)

In the case where the specimen is opaque, or the transmittance can be ignored due to the large thickness thereof, t=0 is established, and the radiation factor can be obtained only from the reflectance.

ε=1−r (C)

The expression (C) was applied to the specimen since the specimen did not transmit an infrared ray, and the radiation factors to the wavelengths of light were calculated.

### FT-IR Spectrum

The average value of the results of the measurement performed twice was designated as the reflectance spectrum. The reflectance spectrum was calibrated with the reflectance of diffuse gold (nominal wavelength region: 2 to 14 μm).

Assuming that the energy intensity at the wavelength λ is E_{bλ}, and the radiation factor of the specimen at the wavelength λ is ελ, the radiation energy intensity of the specimen E_{sλ} is expressed by E_{sλ}=Ελ·E_{bλ}, from a radiation energy distribution of a blackbody at a certain temperature obtained by the plank's expression. In the examples, the radiation energy intensity E_{sλ} of the specimen at 25° C. was obtained by the expression E_{sλ}=ελ·E_{bλ}.

The total energy values of a blackbody and the specimen in a certain wavelength range are obtained as the integrated values of E_{sλ} and E_{bλ} in the wavelength range, and the total radiation factor ε is expressed by the ratio thereof (expression (A) below). In the examples, the total radiation factor ε of the specimen in a wavelength range of from 2 to 14 μm at 25° C. was obtained by the expression. The total radiation factor ε thus obtained was designated as the radiation factor of the specimen.

ε=∫_{λ=2}^{λ=14}Eₛ_{_{λ}}dλ/∫_{λ=2}^{λ=14}E_{b}_{_{λ}}dλ (A)

The structures of Comparative Example 1, Reference Examples 1 to 4, and Examples 1 to 21 were subjected to heat radiation simulation under the following conditions.

Steady Analysis

The flux, the laminar flow, and the gravity were considered.

Heat quantity of heat generating component: 0.225 W (setting value: 1×10⁶ W/m³)

The configuration was performed to make a temperature of approximately 85° C. in the Reference Example 1. A temperature of 85° C. is an assumed temperature of an electronic component generating heat in an ordinary electronic apparatus.

The substrate under the heat generating component was set as an insulator outside the calculated area.

Environmental temperature: 20° C.

Surface thermal conduction coefficient: 6 W/m²·K

The wall opposite to the side receiving the radiation heat was set as a blackbody at 20° C.

The radiation in solid was not considered.

The calculation conditions and the property values are shown in Table 1.

TABLE 1

| | | | Thermal | |
|---|---|---|---|---|
| | | | conduction | |
| | Density | Specific heat | coefficient | |
| Property of material | (kg/m³) | (J/kg · K) | (W/m · K) | Radiation factor |
| Air | assumed as ideal gas | | | |
| Stainless steel | 7,930 | 590 | 16 | 0.1 |
| Adhesive, double- | 1,200 | 1,470 | 0.16 | — |
| sided adhesive tape | | | | |
| PMMA | 1,200 | 1,470 | 0.25 | 1 |
| (resin substrate) | | | | |
| Metal material for | 8,978 | 381 | 390 | 0.19 (Example 1, |
| heat radiation | | | | measured value) |
| (rolled copper foil) | | | | 0.204 (Example 2, |
| | | | | measured value) |
| | | | | 0.206 (Examples 3 |
| | | | | and 6, measured |
| | | | | values) |
| | | | | 0.208 (Examples 4 |
| | | | | and 7) |
| | | | | 0.501 (Example 5, |
| | | | | measured value) |
| Graphite sheet | 850 | 710 | lengthwise 3.5, | 0.39 measured |
| | | | crosswise 1,500 | value |
| High thermal | 2,900 | 1,510 | 1.3 | 0.92 |
| conductive resin A | | | | |
| High thermal | 3,200 | 1,470 | 1 | — |
| conductive resin B | | | | |

The results of the simulation of the test are shown in Table 2.

TABLE 2

| | | Temperature of upper |
|---|---|---|
| | | surface of outer |
| | Temperature of upper | side of heat |
| | surface of heat | generating component |
| | generating component | protective member |
| | (° C.) | (° C.) |
| Comparative Example 1 | 90.2 | 68.7 |
| Reference Example 1 | 85.9 | 66.8 |
| Reference Example 2 | 66.3 | 64.0 |
| Reference Example 3 | 66.4 | 64.1 |
| Reference Example 4 | 66.6 | 66.3 |
| Example 1 | 84.2 | 66.8 |
| Example 2 | 83.8 | 66.8 |
| Example 3 | 81.2 | 66.6 |
| Example 4 | 78.7 | 66.2 |
| Example 5 | 85.1 | 67.0 |
| Example 6 | 83.8 | 66.9 |
| Example 7 | 81.6 | 66.7 |
| Example 8 | 81.1 | 66.6 |
| Example 9 | 80.9 | 66.4 |
| Example 10 | 79.1 | 66.3 |
| Example 10′ | 79.2 | 66.4 |
| Example 11 | 66.4 | 64.0 |
| Example 12 | 66.3 | 64.0 |
| Example 13 | 66.2 | 64.0 |
| Example 14 | 66.7 | 64.4 |
| Example 15 | 66.4 | 64.1 |
| Example 16 | 66.3 | 64.1 |
| Example 17 | 66.2 | 64.0 |
| Example 18 | 66.1 | 63.9 |
| Example 19 | 66.7 | 64.4 |
| Example 20 | 66.4 | 64.1 |
| Example 21 | 66.3 | 64.1 |

### Evaluation Results

All Examples 1 to 21 each had the heat generating component protective member that is provided to cover a part or the entire of the heat generating component and to be spaced from the heat generating component, and the heat radiating member that is provided on the surface of the heat generating component protective member on the side of the heat generating component to be spaced from the surface of the heat generating component on the side of the heat generating component protective member, and the heat radiating member contains a metal material for heat radiation at least on the surface of the heat radiating member on the side of the heat generating component. Accordingly, the heat from the heat generating component was able to be radiated favorably.

It was found from the results of Examples 8 to 10′ showing the examples provided with the high thermal conductive resin A that the heat from the heat generating component was able to be radiated further favorably by providing a resin on the surface of the heat radiating member on the side of the heat generating component.

It was also found that the heat from the heat generating component was able to be radiated more efficiently in Examples 11 to 21 provided with the high thermal conductive resin B between the heat radiating member and the heat generating component than Examples 1 to 10 provided with no high thermal conductive resin.

Comparative Example 1 was inferior in radiation property of the heat from the heat generating component since the heat radiating member was not provided.

This application claims priorities from Japanese Patent Application No. 2016-109455, filed on May 31, 2016, and Japanese Patent Application No. 2016-138063, filed on Jul. 12, 2016, the entire disclosures of which are incorporated herein by reference.

1. A structure having a metal material for heat radiation, comprising:
a heat generating component;
a heat generating component protective member that is provided to cover a part or the entire of the heat generating component and to be spaced from the heat generating component; and
a heat radiating member that is provided on a face of the heat generating component protective member on the side of the heat generating component to be spaced from a surface of the heat generating component on the side of the heat generating component protective member,
wherein the heat radiating member contains a metal material for heat radiation at least on a surface of the heat radiating member on the side of the heat generating component.

2. The structure having a metal material for heat radiation according to claim 1, wherein the heat radiating member is constituted by the metal material for heat radiation.

3. The structure having a metal material for heat radiation according to claim 1, wherein the heat radiating member contains the metal material for heat radiation and a graphite sheet in this order from the side of the heat generating component.

4. The structure having a metal material for heat radiation according to claim 1, wherein the heat radiating member contains a plurality of the metal materials for heat radiation.

5. The structure having a metal material for heat radiation according to claim 3, wherein the heat radiating member contains a plurality of the graphite sheets.

6. The structure having a metal material for heat radiation according to claim 4, wherein the heat radiating member contains a plurality of graphite sheets.

7. The structure having a metal material for heat radiation according to claim 1, wherein the metal material for heat radiation has a thickness of 18 μm or more.

8. The structure having a metal material for heat radiation according to claim 1, wherein the metal material for heat radiation has a color difference ΔL based on JIS Z8730 satisfying ΔL≦−40 on a surface of the metal material for heat radiation on the side of the heat generating component.

9. The structure having a metal material for heat radiation according to claim 1, wherein the metal material for heat radiation has a radiation factor of 0.03 or more on a surface of the metal material for heat radiation on the side of the heat generating component.

10. The structure having a metal material for heat radiation according to claim 1, wherein the metal material for heat radiation has a surface treatment layer provided on a surface of the metal material for heat radiation on the side of the heat generating component, and the surface treatment layer contains one or more layers selected from the group consisting of a roughening treatment layer, a heat resistant layer, a rust preventing layer, a chromate treatment layer, a silane coupling treatment layer, a plated layer, and a resin layer.

11. The structure having a metal material for heat radiation according to claim 1, wherein the metal material for heat radiation contains copper, a copper alloy, aluminum, an aluminum alloy, iron, an iron alloy, nickel, a nickel alloy, gold, a gold alloy, silver, a silver alloy, a platinum group metal, a platinum group metal alloy, chromium, a chromium alloy, magnesium, a magnesium alloy, tungsten, a tungsten alloy, molybdenum, a molybdenum alloy, lead, a lead alloy, tantalum, a tantalum alloy, tin, a tin alloy, indium, an indium alloy, zinc, or a zinc alloy.

12. The structure having a metal material for heat radiation according to claim 1, wherein the metal material for heat radiation is a metal strip, a metal plate, or a metal foil.

13. The structure having a metal material for heat radiation according to claim 1, wherein the metal material for heat radiation has a surface roughness Sz of 5 μm or more measured with a laser microscope with laser light having a wavelength of 405 nm on a surface of the metal material for heat radiation on the side of the heat generating component.

14. The structure having a metal material for heat radiation according to claim 1, wherein the metal material for heat radiation has a surface roughness Sa of 0.13 μm or more measured with a laser microscope with laser light having a wavelength of 405 nm on a surface of the metal material for heat radiation on the side of the heat generating component.

15. The structure having a metal material for heat radiation according to claim 1, wherein the metal material for heat radiation has a surface roughness Sku of 6 or more measured with a laser microscope with laser light having a wavelength of 405 nm on a surface of the metal material for heat radiation on the side of the heat generating component.

16. The structure having a metal material for heat radiation according to claim 1, wherein the metal material for heat radiation satisfies one or more of the following items (1) to (5) on a surface of the metal material for heat radiation on the side of the heat generating component:
(1) the surface on the side of the heat generating component having a color difference ΔL based on JIS 28730 satisfying ΔL≦−40;
(2) the surface on the side of the heat generating component having a radiation factor of 0.03 or more;
(3) the surface on the side of the heat generating component having a surface roughness Sz of 5 μm or more measured with a laser microscope with laser light having a wavelength of 405 nm;
(4) the surface on the side of the heat generating component having a surface roughness Sa of 0.13 μm or more measured with a laser microscope with laser light having a wavelength of 405 nm; and
(5) the surface on the side of the heat generating component having a surface roughness Sku of 6 or more measured with a laser microscope with laser light having a wavelength of 405 nm.

17. The structure having a metal material for heat radiation according to claim 1, wherein the heat radiating member further contains a substance having thermal conductivity on a face of the heat radiating member on the side of the heat generating component.

18. The structure having a metal material for heat radiation according to claim 17, wherein the substance has a thermal conductivity of 0.5 W/(m·K) or more.

19. A printed circuit board comprising the structure having a metal material for heat radiation according to claim 1.

20. An electronic apparatus comprising the structure having a metal material for heat radiation according to claim 1.

21. A metal material for heat radiation comprising one or more surfaces, at least one of the surfaces satisfying one or more of the following items (1) to (5), the metal material for heat radiation being to be adhered with a graphite sheet and to be used as a heat radiating member:
(1) the surface having a color difference ΔL based on JIS 28730 satisfying ΔL≦−40;
(2) the surface having a radiation factor of 0.03 or more;
(3) the surface having a surface roughness Sz of 5 μm or more measured with a laser microscope with laser light having a wavelength of 405 nm;
(4) the surface having a surface roughness Sa of 0.13 μm or more measured with a laser microscope with laser light having a wavelength of 405 nm; and
(5) the surface having a surface roughness Sku of 6 or more measured with a laser microscope with laser light having a wavelength of 405 nm.
